(19) United States
(12) Patent Application Publication
(10) Pub. No.: US 2014/0209453 A1
(43) Pub. Date: Jul. 31, 2014

(54) METHOD FOR PREDICTING PLASMA MICRO-ARCING, AND METHOD FOR CONTROLLING PLASMA PROCESS OF PRODUCTION EQUIPMENT USING THE SAME

(71) Applicant: SAMSUNG ELECTRONICS CO., LTD., Suwon-si (KR)

(72) Inventors: Hyun Su JUN, Hwaseong-si (KR); TaeRang KIM, Ansan-Si (KR); Jino PARK, Osan-si (KR)

(73) Assignee: SAMSUNG ELECTRONICS CO., LTD., Suwon-si (KR)

(21) Appl. No.: 14/144,844

(22) Filed: Dec. 31, 2013

(30) Foreign Application Priority Data
Jan. 31, 2013 (KR) 10-2013-0011174

(51) Int. Cl. H01J 37/32; G01J 1/44

(52) U.S. Cl. CPC H01J 37/32944; G01J 1/44
USPC 204/192.33; 134/18; 250/214.1

(57) ABSTRACT

A method for predicting plasma micro-arcing includes obtaining a spectrum signal in a given plasma process, classifying an optical intensity of the spectrum signal into soft and hard arcing events according to an amplitude of the optical intensity of the spectrum signal, separately counting a number of occurrences of the soft arcing event in a given unit time, comparing the number of occurrences of the soft arcing event during the given unit time with the number of occurrences of the soft arcing event during a previous unit time, and determining that a number of occurrences of the hard arcing event will increase during a next unit time subsequent to the given unit time, when the number of occurrences of the soft arcing event during the given unit time increases in comparison with the number of occurrences of the soft arcing event during the previous unit time.

### CROSS-REFERENCE TO RELATED APPLICATION

Korean Patent Application No. 10-2013-0011174, filed on Jan. 31, 2013, in the Korean Intellectual Property Office, and entitled: “Method for Predicting Plasma Micro-Arcing, and Method for Controlling Plasma Process of Production Equipment Using the Same,” is incorporated by reference herein in its entirety.

### BACKGROUND

1. Field

The present disclosure herein relates to a semiconductor manufacturing method, and more particularly, to a method for predicting plasma micro-arcing, and a method for controlling a plasma process of production equipment using the same.

2. Description of the Related Art

In general, semiconductor devices are manufactured through multiple unit processes including a thin film deposition process and an etching process. Among others, the etching process is mostly performed through plasma reaction. The plasma reaction occurs by radio frequency (RF) power. The RF power may induce arcing during the plasma reaction. The arcing may lead to changes in plasma process parameters or lead to product fails.

### SUMMARY

The present disclosure provides a method for predicting plasma micro-arcing, which is capable of detecting plasma micro-arcing fails in advance, and a method for controlling a plasma process of production equipment using the same.

The present disclosure also provides a method for predicting plasma micro-arcing, which is capable of suppressing plasma micro-arcing, and a method for controlling a plasma process of production equipment using the same.

Embodiments provide a method for predicting plasma micro-arcing including obtaining a spectrum signal in a given plasma process, classifying an optical intensity of the spectrum signal into a soft arcing event and a hard arcing event according to an amplitude of the optical intensity of the spectrum signal, separately counting a number of occurrences of the soft arcing event in a given unit time, comparing the number of occurrences of the soft arcing event during the given unit time with the number of occurrences of the soft arcing event during a previous unit time, and determining that a number of occurrences of the hard arcing event will increase during a next unit time subsequent to the given unit time, when the number of occurrences of the soft arcing event during the given unit time increases in comparison with the number of occurrences of the soft arcing event during the previous unit time.

In some embodiments, the soft arcing event and the hard arcing event may be calculated from a distribution function having a variable of a standard deviation and an optical intensity amplitude. The distribution function may include a normal distribution function.

In other embodiments, the number of occurrences of the soft arcing event may be counted in a logarithmic scale distribution function which is transformed from the normal distribution function.

In still other embodiments, the logarithmic scale distribution function may have a normal section, a soft arcing section, and a hard arcing section. The soft arcing section may include a first soft arcing section of a first arcing events and a second soft arcing section a second arcing events. the first soft arcing section may range between 8×standard deviation and 11×standard deviation in the logarithmic scale function or the normal distribution function, and the second soft arcing section may range between 11×standard deviation and 15×standard deviation in the logarithmic scale function or the normal distribution function.

In even other embodiments, it may be predicted that the number of occurrences of the hard arcing event during the next unit time will increase, when the number of the second soft arcing events in the second soft arcing section during the given unit time is greater than the number of the second soft events during the previous unit time by a threshold value or more.

In other embodiments of the inventive concept, methods for controlling a plasma process of production equipment, include: obtaining a spectrum signal from a plasma reaction in a chamber; obtaining a high-frequency signal by removing noise from the spectrum signal; calculating at least one distribution function having a soft arcing section of a soft arcing event and a hard arcing section of a hard arcing event depending on an optical intensity of the high-frequency signal; transforming the distribution function to a logarithmic scale function; separately counting number of occurrences of the soft arcing event in every unit time during the soft arcing section in the logarithmic scale function; comparing the number of occurrences of the soft arcing event during a given unit time with the number of occurrences of the soft arcing events during a previous unit time; and determining that number of occurrences of the hard arcing event will increase during a next unit time subsequent to the given unit time, and outputting an interlock control signal to allow the plasma reaction not to be continuously performed during the next unit time, when the number of occurrences of the soft arcing event during the given unit time increases in comparison with that during the previous unit time.

In further embodiments, the method may further include cleaning the chamber after the outputting of the interlock control signal.

In still further embodiments, the cleaning of the chamber may include in-situ drying cleaning.

Embodiments also provide a method for controlling a plasma process of production equipment including obtaining a spectrum signal of a given plasma process in a chamber, classifying an optical intensity of the spectrum signal into a soft arcing event and a hard arcing event according to an amplitude of the optical intensity of the spectrum signal, separately counting a number of occurrences of the soft arcing event in a given unit time, comparing the number of occurrences of the soft arcing event during the given unit time with the number of occurrences of the soft arcing event during a previous unit time, and outputting an interlock control signal to discontinue the plasma process in the chamber, when the number of occurrences of the soft arcing event during the given unit time increases in comparison with the number of occurrences of the soft arcing event during the previous unit time.

Counting the number of occurrences of the soft arcing event in the given unit time may include counting the number of occurrences of the soft arcing event during an entire process stage of a predetermined number of objects in the chamber.

Outputting the interlock signal may occur before inputting new objects into the chamber for the process stage.

The previous unit of time may be a predetermined reference value.

The previous unit of time may be measured during an entire process stage of a predetermined number of previous objects in the chamber.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic view of plasma equipment according to an embodiment;

FIG. 2 illustrates a flowchart of a method for controlling a plasma process of production equipment according to an embodiment;

FIG. 3 illustrates a graph showing a spectrum signal;

FIG. 4 illustrates a graph showing a high-frequency signal obtained by removing a low-frequency signal from the spectrum signal;

FIG. 5 illustrates a graph showing an enlarged view of a plasma micro-arcing event of the high-frequency signal;

FIG. 6 illustrates a graph of a distribution function 76 showing an optical intensity of the high-frequency signal according to its amplitude;

FIG. 7 illustrates a graph showing a logarithmic scale distribution function of the normal distribution function in FIG. 6;

FIG. 8 illustrates a schematic view sequentially illustrating a damage of a thin film caused by a direct current breakdown voltage;

FIG. 9 illustrates a graph schematically showing a dielectric breakdown voltage drop due to the damage of the thin film in FIG. 8;

FIGS. 10 to 12 illustrate graphs respectively showing the number of occurrences of a first soft arcing event, the number of occurrences of a second soft-arcing event, and the number of occurrences of a hard arcing event, versus a device fail rate;

FIG. 13 illustrates a graph showing the relationship between the second soft arcing event and the hard arcing event; and

FIG. 14 illustrates a block diagram schematically illustrating the control system in FIG. 1, for explaining a method for controlling a plasma process of production equipment according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. Like reference numerals refer to like elements throughout.

In the following description, the technical terms are used only for explaining specific exemplary embodiments without limiting implementation thereof. The terms of a singular form may include plural forms unless specifically mentioned. The meaning of ‘comprises’ and/or ‘comprising’ specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto.

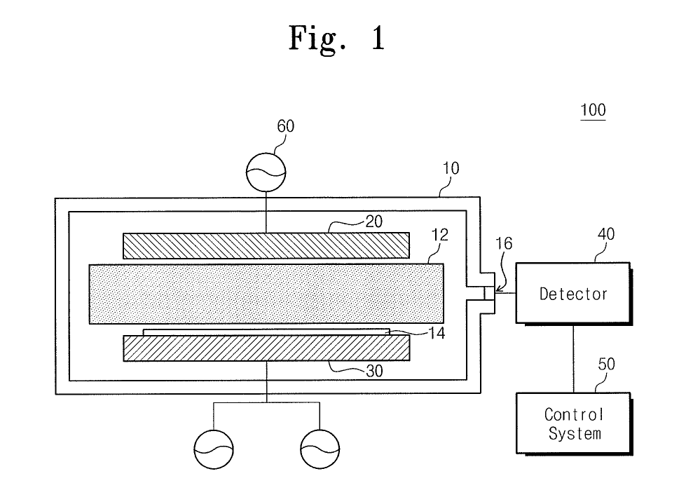

FIG. 1 illustrates a schematic view of plasma equipment, which illustrates a method for controlling a plasma process of production equipment according to an embodiment.

Referring to FIG. 1, plasma equipment 100 may include a chamber 10, an upper electrode 20, a lower electrode 30, a detector 40, and a control system 50.

The chamber 10 may provide a space independent from the outside so as to induce plasma 12. The plasma 12 may be induced inside the chamber 10 by radio frequency (RF) power 60 applied from the upper electrode 20 and the lower electrode 30. The RF power 60 may be supplied to the upper electrode 20 and the lower electrode 30 from a power supply (not shown) and a matcher (not shown). The power supply and the matcher may be controlled by a control signal of the control system 50. The upper electrode 20 and the lower electrode 30 are disposed above and below a wafer 14, respectively. The upper electrode 20 may include a shower head for jetting a plasma gas or an etching gas onto the wafer 14. The lower electrode 30 may include a chuck for fixing the wafer 14.

The plasma 12 may be seen from the outside of the chamber 10 through a view port 16. The detector 40 may be disposed in the view port 16 of the chamber 10. The plasma 12 may generate its own spectrum depending on a plasma gas or an etching gas and types of an etching target thin film which is responsive thereto. The detector 40 may include a photodiode generating a spectrum signal. The spectrum signal may be input to the control system 50.

The control system 50 may monitor the plasma 12 using the spectrum signal. The plasma 12 may maximize the anisotropic etching property of the etching gas. Micro-arcing may occur during an etching process using the plasma 12, and the micro-arcing may lead to a failure of the etching process. The etching process failure caused by the micro-arcing may be observed as local damages on the surface of the wafer 14. The micro-arcing may be divided into direct current (DC) arcing and radio frequency (RF) arcing according to its source.

For example, the DC arcing may occur due to cathodic electron emission. In another example, the DC arcing may occur due to evaporation of a thin insulator on a metal surface.

For example, the RF arcing may occur due to a sudden explosive field emission at a ground electrode (not shown). Field emission electrons may be accelerated by a sheath voltage to form a strong electron stream. The field emission electrons may result in a plasma potential collapse and a sharp increase in the density of the plasma 12. Also, high floating potential may be associated with the number of micro-arcing occurrences.

In another example, the RF arcing may result from a thin film breakdown inside the chamber 10. That is, if an inner wall of the chamber 10 is coated with a thin insulation film, e.g., an yttrium oxide (Y₂O₃) film or an aluminum oxide (Al₂ O₃) film, the thin insulation film may be continuously damaged by the ion bombardment of a high plasma potential and the electrical stress of an RF voltage. The thin insulation film may emit electrons accumulated therein when it is broken down during a plasma process. The emitted electrons may serve as an electrical trigger for micro-arcing which is similar to that caused by the field emission electrons.

Therefore, the micro-arcing is closely related to the damage of the thin insulation film inside the chamber 10. The damage of the thin insulation film caused by the plasma 12 may gradually increase, and the micro-arcing may be observed from changes in the spectrum intensity amplitude of the plasma 12. The changes in the plasma 12 may be nearly invisible to the naked eye. The micro-arcing may be classified into soft arcing and hard arcing depending on the intensity of the spectrum. The soft arcing may rarely damage the thin insulation film. On the contrary, the hard arcing may severely damage the thin insulation film. The hard arcing may appear after frequent occurrences of the soft arcing.

Hereinafter, description will be given of a method for controlling a plasma process, which is capable of predicting micro-arcing fails such as hard arcing.

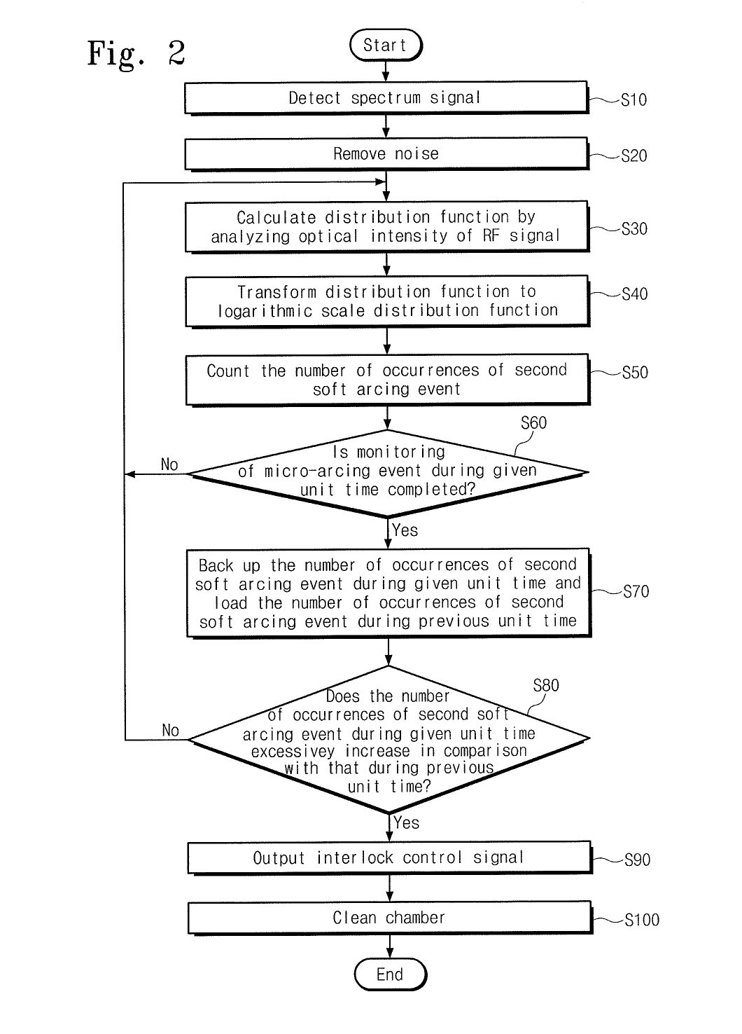

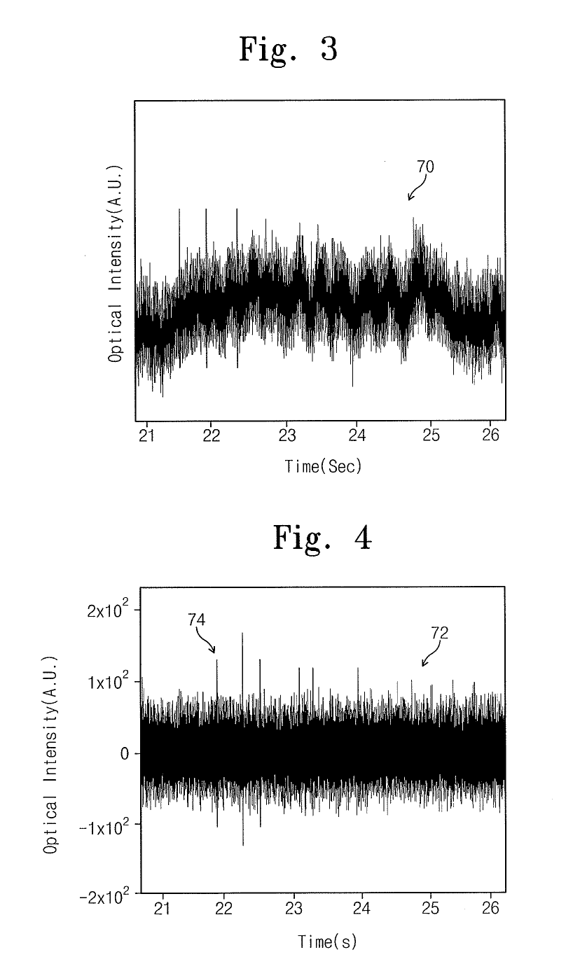

FIG. 2 illustrates a flowchart of a method for controlling a plasma process of production equipment according to an embodiment. FIG. 3 is a graph showing a spectrum signal.

Referring to FIGS. 1-3, the detector 40 detects a spectrum signal 70 (S10). The spectrum signal 70 may be measured continuously. The spectrum signal 70 may include a low-frequency signal and a high-frequency signal, e.g., the spectrum signal 70 may be about 1 MHz. An average optical intensity of the low-frequency signal changes slower than 1 KHz during a process according to plasma conditions, e.g., gas pressure, RF power, and etch by-products. The low-frequency signal may be noise.

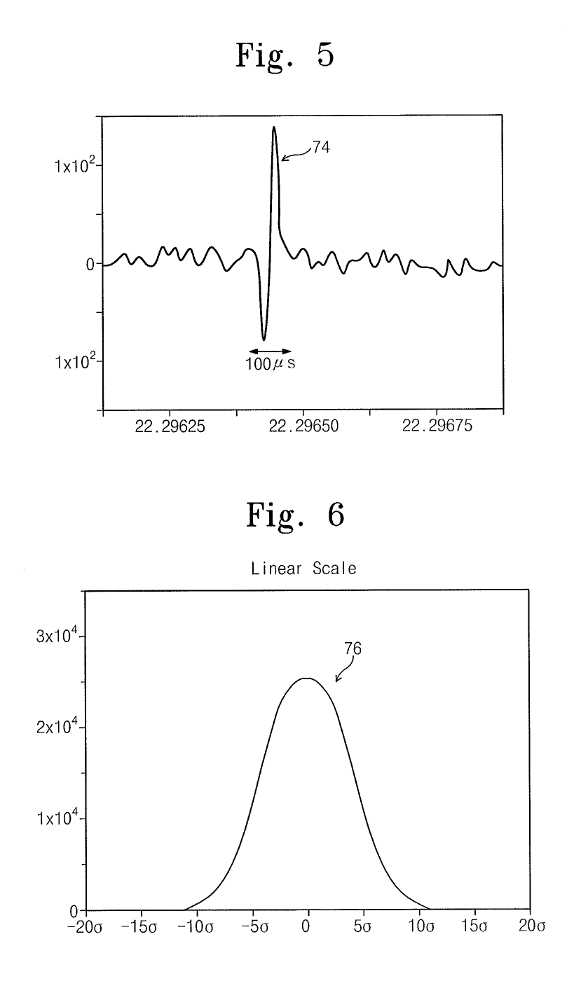

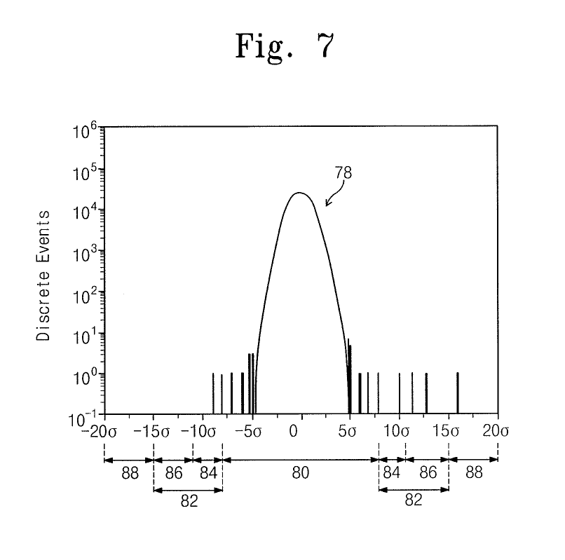

FIG. 4 illustrates a graph showing a high-frequency signal 72 obtained by removing a low-frequency signal from the spectrum signal 70. FIG. 5 is a graph showing an enlarged view of a plasma micro-arcing event 74 of the high-frequency signal 72.

Referring to FIGS. 1, 2, and 4-5, the control system 50 obtains the high-frequency signal 72 by removing the low-frequency signal, e.g., noise, from the spectrum signal 70 (S20). The noise may be removed by differentiation of the spectrum signal 70. The central value of the optical distribution of the high-frequency signal 72 may approach nearly 0, e.g., FIGS. 4-5. The high-frequency signal 72 may include the micro-arcing event (MAE) 74. The micro-arcing event may correspond to a micro-arcing signal. In the micro-arcing event 74, the optical intensity of the plasma 12 is generated very strongly and irregularly, which is different from the background optical intensity. The micro-arcing event 74 may have a duration time of about 10 μs to about 100 μs, e.g., FIG. 5. The spectrum signal 70 may have a term shorter than about 10 μs, i.e., a frequency of about 1 MHz.

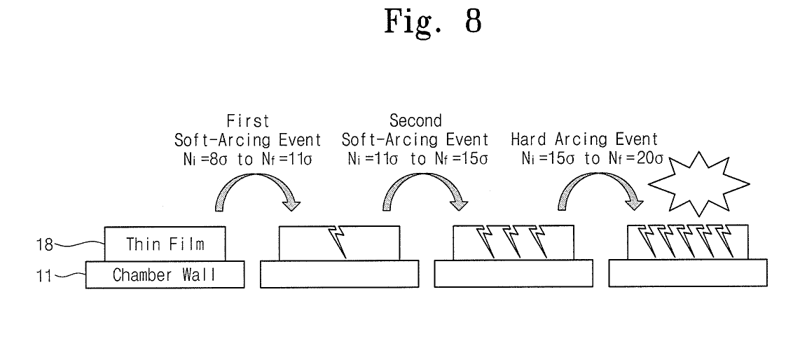

FIG. 6 illustrates a graph of a distribution function 76 showing an optical intensity of the high-frequency signal 72 according to its amplitude.

Referring to FIGS. 1, 2, and 6, the distribution function 76 is calculated by analyzing the optical intensity of the high-frequency signal 72 on a linear scale (S30). The distribution function 76 may show the distribution of the optical intensity of the spectrum signal 70, which is detected during a sub-unit time. For example, the sub-unit time may be about 10 seconds to about 1 minute. The unit time may include a halt lot, or 30 minutes to one hour. The unit time will be more fully described later.

The distribution function 76 of the optical intensity may satisfy the Gaussian distribution. The normal distribution function may match the probability of the optical intensity. The optical intensity distribution may have a standard deviation (σ(t). Assuming that the MAE exists between Nᵢₒ and N_{fo}, the probability of the optical intensity, i.e., PΔN may be calculated from the following Eq. (1):

$$\begin{matrix}{P}_{Δ N} = \frac{1}{σ ( t ) \sqrt{2 π}} {\int }_{{N}_{i}}^{{N}_{f}} {e}^{- \frac{N}{2}} d N \\ = \frac{1}{2 σ ( t )} [ Erf ( \frac{{N}_{f}}{\sqrt{2}} ) - Erf ( \frac{{N}_{i}}{\sqrt{2}} ) ]\end{matrix} \qquad Eq . ( 1 )$$

In Eq. (1), Nᵢ and N_{f} are real numbers defined by a device fail rate, and σ(t) is a standard deviation of the optical amplitude. The optical intensity amplitude measured from the plasma 12 may be expressed by the standard deviation (optical amplitude=Nσ). The probability distribution may be represented as an error function.

The identification of the micro-arcing event 74 using the probability distribution is advantageous to a mass-production system. Conditions of the view port 16 are all different from one another for each chamber 10 in a semiconductor production line, and window clogging may vary with an operation time of the chamber 10. If the micro-arcing event 74 is identified using the probability distribution, the standard deviation (σ(t)) also varies with the window clogging. Thus, there is little or no data distortion of the micro-arcing event 74 according to an RF on-time. That is, the distribution function having the standard deviation as a variable shows a relative difference in intensity. Therefore, the same classification criteria for the micro-arcing event 74 may be applied to different chambers 10.

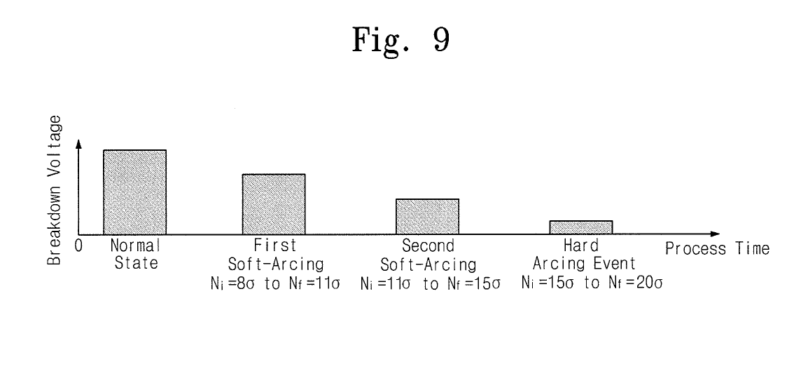

FIG. 7 illustrates a graph showing a logarithmic scale distribution function of the normal distribution function in FIG. 6.

Referring to FIGS. 1, 2, and 7, the distribution function 76 is transformed to a logarithmic scale distribution function 78 (S40). The optical intensity distribution of the logarithmic scale distribution function 78 may be discontinuous beyond ±5σ. The logarithmic scale distribution function 78 enables the micro-arcing event 74 to be distinguished from the background optical intensity distribution. For example, the logarithmic scale distribution function 78 may be divided into a normal section 80, a soft arcing section 82, and a hard arcing section 88, according to a multiple of the standard deviation. Most of the plasma 12 may have the optical intensity distribution in the normal section 80. For example, the normal section may range from 0 to 8σ. The soft arcing section 82 may be divided into a first soft arcing section 84 and a second soft arcing section 86. The first soft arcing section 84 may range between 8σ and 11σ. The second soft arcing section 86 may range between 11σ and 15σ. The optical intensity distributions shown in the first and second soft arcing sections 84 and 86 correspond to a first soft arcing event and a second soft arcing event, respectively. The hard arcing section 88 may range between 15σ and 20σ. Likewise, the optical intensity distribution shown in the hard arcing section 88 corresponds to a hard arcing event. The hard arcing event may lead to fatal device fails. The control system 50 may predict the occurrence of the hard arcing event in advance, from the occurrence of the second soft arcing event. The probability of the hard arcing event occurrence may be closely related with the probability of the second soft arcing event occurrence mathematically. The probability of the second soft arcing event occurrence and the probability of the hard arcing event occurrence may be expressed by Eq. (2) below.

$${P}_{Hard} = \frac{1 - Erf ( \frac{{N}_{i}}{\sqrt{2}} )}{Erf ( \frac{{N}_{f}}{\sqrt{2}} ) - Erf ( \frac{{N}_{i}}{\sqrt{2}} )} {P}_{Soft\_II} \qquad Eq . ( 2 )$$

Herein, P_{Hard} is the probability of the hard arcing event occurrence, and P_{soft}_{_{—}}_{II} is the probability of the second soft arcing event occurrence. Ni and Nf are constants determined by an operator. By differentiating both sides of Eq. (2) by time, Eq. (3) will be obtained.

$$\frac{\partial }{\partial t} {P}_{Hard} ∝ \frac{\partial }{\partial t} {P}_{Soft\_II} \qquad Eq . ( 3 )$$

The probability of the second soft arcing event occurrence (P_{soft}_{_{—}}_{II}) and the probability of the hard arcing event occurrence (P_{Hard}) may be linearly proportional to each other. Therefore, if the probability of the second soft arcing event occurrence is obtained, the probability of the hard arcing event occurrence may be predicted. Eq. (3) may match up to the probability of plasma micro-arcing event occurrence caused by thin insulation breakdown.

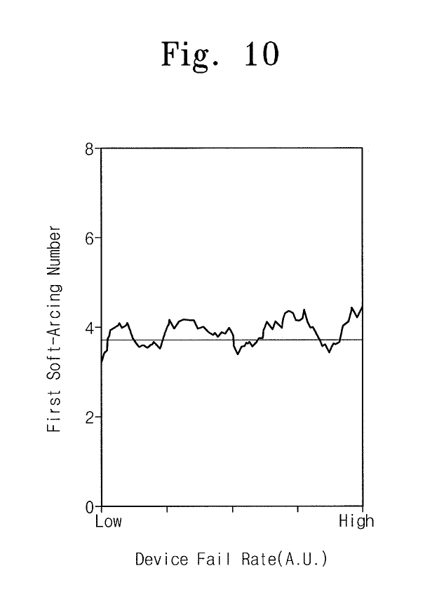

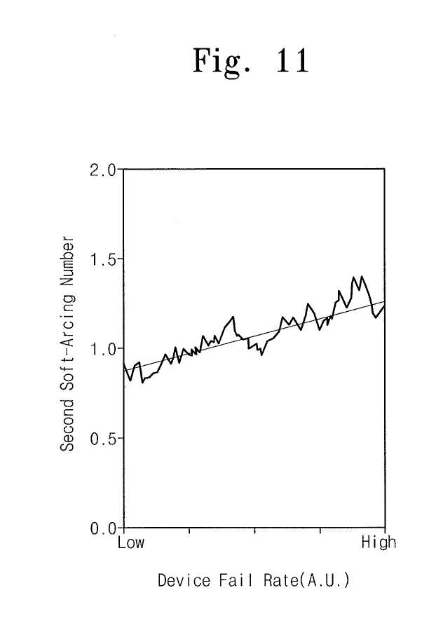

FIG. 8 illustrates a schematic view sequentially illustrating damage of a thin film 18 caused by a DC breakdown voltage. FIG. 9 illustrates a graph schematically showing a dielectric breakdown voltage drop due to the damage of the thin film 18 in FIG. 8.

Referring to FIGS. 8 and 9, a damage process of all the thin films 18 existing on an inner wall 11 of the chamber 10 may be initiated by the first soft arcing event, which hardly affects semiconductor device fails. The first soft arcing event may progress to the second soft arcing event, and the second soft arcing event may then progress to the hard arcing event. An area of the thin film 18 damaged by the second soft arcing event may gradually increase, e.g., as compared to an area damaged by the first soft arcing event. The thin film 18, which has been damaged by the second soft arcing event, has a sufficiently low DC breakdown voltage. Also, the thin film 18 may be susceptible to dielectric breakdown even by small plasma damage. That is, the thin film 18 may have poor resistance to RF power arcing. The damage of the thin film 18 may accumulate, thereby gradually lowering the DC breakdown voltage. As such, a hard arcing event may directly damage a device, regardless of a number of occurrences of the hard arcing event. For this reason, predicting the occurrence of the hard arcing event by using the correlation between the second soft arcing event and the hard arcing event, rather than stopping a process after occurrence of the hard arcing event, may substantially reduce a number of damaged products.

In detail, referring to FIG. 2 again, the control system 50 counts the number of occurrences of the second soft arcing event (S50). Here, the second soft arcing event occurs during a sub-unit time. The number of the second soft arcing events occurring during the sub-unit time may be cumulatively counted.

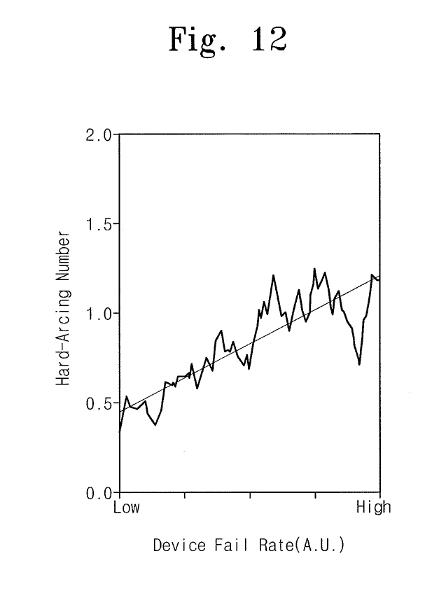

FIGS. 10 to 12 illustrate graphs respectively showing the number of occurrences of the first soft arcing event, the number of occurrences of the second soft-arcing event, and the number of occurrences of the hard arcing event, versus a device fail rate.

Referring to FIGS. 10 to 12, a device fail rate is constant regardless of the number of occurrences of the first soft arcing event. However, the device fail rate increases as the number of occurrences of each of the second soft arcing event and the hard arcing event increases. The number of occurrences of the second soft arcing event may have a certain gradient with respect to a device fail rate. The number of occurrences of the hard arcing event may have a higher gradient with respect to the device fail rate than the number of occurrences of the second soft arcing event. The device fail rate may sharply increase by the hard arcing event rather than the second soft arcing event. As the hard arcing event may damage the device more rapidly than the second soft arcing event, it is desirable to predict the occurrence of the hard arcing event using the second soft arcing event, i.e., before the hard arcing event actually occurs.

Therefore, the control system 50 may predict an increase in the number of occurrences of the hard arcing event during a next unit time by counting the number of occurrences of the second soft arcing event during a given unit time.

Thereafter, the control system 50 determines whether monitoring of plasma micro-arcing during the given unit time is completed (S60). The procedure from operation S30 to operation S60 may be repeatedly performed until the monitoring of plasma micro-arcing during the given unit time is completed. The control system 50 may obtain one distribution function every time the procedure from operation S30 to operation S60 is performed. One distribution function may be obtained for every one sub-unit time.

As described above, in operation S50, the number of occurrences of the second soft arcing event may be cumulatively counted during a predetermined time. For example, the predetermined time, i.e., the unit time, may be set as a unit of cumulative etching process time or as process lot, e.g., length of time required to complete a process or to complete processing a predetermined number of items. For example, the unit time may correspond to a half lot, e.g., length of time required to process half a lot. The term “lot” refers to a unit by which the wafers 14 are transferred in a semiconductor production line, e.g., via a cassette or a Front Opening Unified Pod (FOUP), so the lot may correspond to a number of wafers in the cassette or FOUP. For example, one lot may include about twenty four wafers 14, so a half lot may include about twelve wafers 14. Therefore, if an etching process using plasma is performed on one wafer 14 for about three to five minutes, the unit time may be about 36 minutes to about 60 minutes, i.e., a length of time required to etch half a lot (twelve wafers 14). Thus, the second soft arcing event may be cumulatively counted for about 36 minutes to about 1 hour.

Afterwards, if the unit time has passed, the control system 50 backs up the number of occurrences of the second soft arcing event during the given unit time, i.e., a current unit time, and loads the number of occurrences of the second soft arcing event during a previous unit time (S70). An increase or decrease in the cumulative number of occurrences of the second soft arcing event between the previous unit time and the given unit time is closely relation to the occurrence of the hard arcing event in a following unit time. Therefore, the number of occurrences of the second soft arcing event is counted. When the number of occurrences of the second soft arcing event during the previous unit time is not present, i.e., when there is no comparison value to determine a relative increase or decrease in the number of occurrences, a predetermined value may be input by an operator or an algorithm.

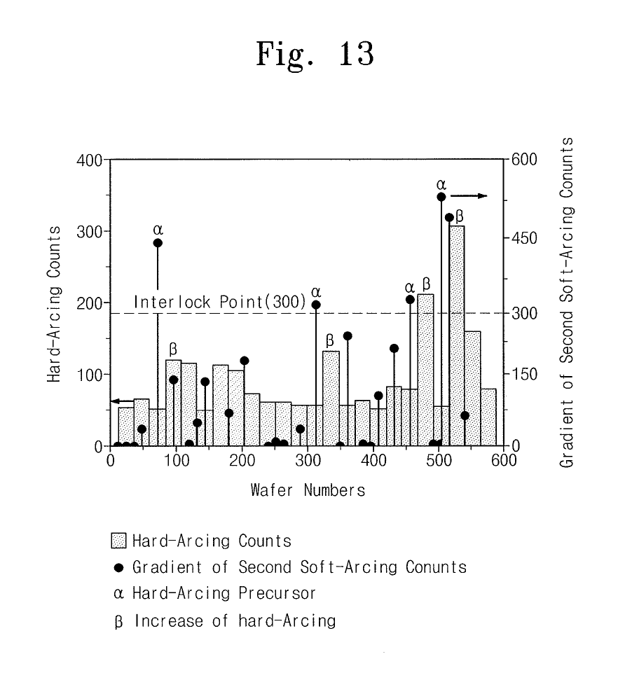

FIG. 13 illustrates a graph showing the relationship between the second soft arcing event and the hard arcing event.

Referring to FIGS. 2 and 13, the control system 50 determines whether the number of occurrences of the second soft arcing event excessively increases (S80). When the number of occurrences of the second soft arcing event during the given unit time excessively increases in comparison with that during the previous unit time, the number of occurrences of the hard arcing event may increase during the next unit time. This is because a thin insulation breakdown area, which may lead to the hard arcing event, may increase when the probability of the second soft arcing event occurrence increases over time. The probability of the hard arcing event occurrence may linearly increase in proportion to time.

For example, when the number of occurrences of the second soft arcing event increases by about 300 times or more per a half lot, the number of occurrences of the hard arcing event during a following half lot may increase. Here, the occurrence of the hard arcing event is indicated in a lot unit, and a gradient of the second soft arcing event occurrence is indicated in a half lot unit. The number of occurrences of the second soft arcing event may excessively increase in a half lot before the frequency of hard arcing events increases. The gradient of the second soft arcing event occurrence may be a precursor to an increase in the hard arcing events. When the number of occurrences of the second soft arcing event increases, the control system 50 may predict that the hard arcing event will frequently occur after a subsequent half lot. When the number of occurrences of the second soft arcing event during the given unit time does not increase in comparison with that during the previous unit time, the control system 50 may be updated to monitor a plasma micro-arcing event during a new next unit time.

A point when the increase in the number of occurrences of the second soft arcing event reaches 300 is an interlock point. The index α in FIG. 13 indicates a hard arcing precursor in which the increase in number of occurrences of the second soft arcing event is 300 or more, and the index β indicates the timing when the number of occurrences of the hard arcing event significantly increases immediately after the occurrence of α. Plasma micro-arcing event was monitored on 600 sheets or more of the wafers 14, and resultantly, it can be verified that the index β always appears after the detection of the index α.

When the increase in number of occurrences of the second soft arcing event is 300 or lower, the consistency of the hard arcing event prediction may be deteriorated. This predicts that there is a threshold value in the increased number of occurrences of the second soft arcing event, which is required to develop the second soft arcing event to the hard arcing event. That is, this means that the number of occurrences of the hard arcing event can increase only if there is a sufficient increase in the number of occurrences of the second soft arcing event during a unit time. This characteristic is very similar to sputtering process yield characteristic caused by ion bombardment. For sputtering of the thin film 18, ion bombardment energy is required, which is equal to or higher than the threshold energy which can overcome bonding energy around molecules. This means that the number of occurrences of the second soft arcing event should be equal to or greater than the threshold value in order to increase the number of occurrences of the hard arcing event.

Referring back to FIG. 2, when the control system 50 determines that the number of occurrences of the second soft arcing event excessively increases, the control system 50 recognizes that the possibility of the hard arcing event occurrence is high, and thus outputs an interlock control signal (S90). Therefore, according to example embodiments, input of the wafers 14 into the chamber 10 may be stopped by the interlock control signal before occurrence of the plasma micro-arcing event, e.g., before damage to the wafer 14 occurs. In contrast, a conventional interlock control signal is used mostly for already damaged products in the chamber 10 or process recovery after occurrence of the plasma micro-arcing event.

Therefore, a method for controlling a plasma process according to embodiments prevents plasma process fails by predicting an increase in the number of occurrences of the hard arcing event in advance without detrimental effects on the plasma production process. As such, the method for controlling a plasma process of production equipment according to embodiments can predict a micro-arcing event during the plasma process and effectively suppress the plasma micro-arcing.

Finally, a cleaning process of the chamber 10 may be performed (S100). The cleaning process may include an in-situ dry (ISD) cleaning process, and a wet cleaning process. The ISD cleaning process is a process of removing or stabilizing the thin film 18 which has been damaged on the inner wall 11 of the chamber 10 due to plasma. The wet cleaning process is a process of cleaning the inner wall 11 of the chamber 10 using a chemical liquid or organic solvent by an operator. A seasoning process may be performed after the wet cleaning. The seasoning process may include a preliminary process of forming the thin film 18 on the inner wall 11 of the chamber 10. When the cleaning process and the seasoning process are completed, a plasma process may be subsequently performed.

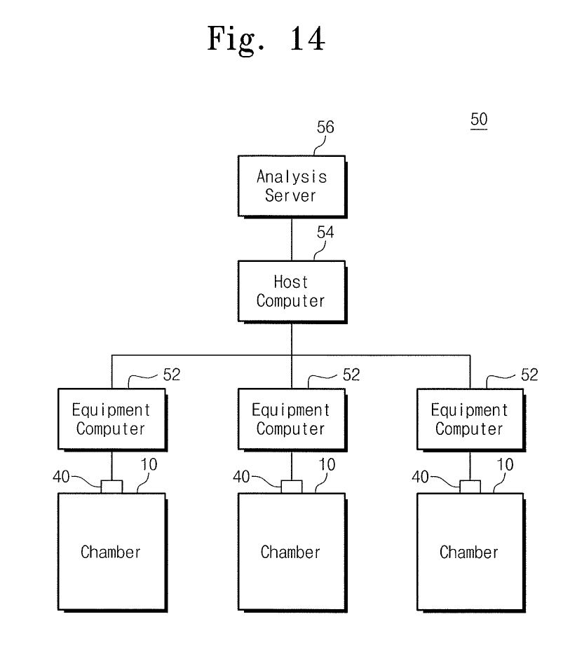

FIG. 14 illustrates a block diagram schematically illustrating the control system 50 in FIG. 1, for explaining the method for controlling a plasma process of production equipment according to an embodiment.

Referring to FIGS. 1 and 14, the control system 50 may include an equipment computer 52, a host computer 54, and an analysis server 56. The equipment computer 52 may deliver the spectrum signal 70 of the detector 40 to the host computer 54 and the analysis server 56. The host computer 54 may provide information regarding the wafer 14, e.g., where the plasma reaction 12 is performed, to the analysis server 56. The analysis server 56 may predict the increase in the number of occurrences of the hard arcing event during a next unit time by counting the number of occurrences of the second soft arcing event in the plasma 12 during a given unit time.

When predicting the increase in the number of occurrences of the hard arcing event, the host computer 54 outputs the interlock control signal to the equipment computer 52. The equipment computer 52 may stop inputting the wafer 14 into the chamber 10. The equipment computer 52 may allow the ISD process for the chamber 10 to be performed in a state where the wafer 14 is removed from the inside of the chamber 10. Also, the chamber 10 may be subjected to a wet cleaning process. The ISD process and the wet cleaning process may be regularly performed for preventive maintenance (PM). Embodiments are not limited to the above and various modifications can be implemented, e.g., the host computer 54 and the equipment computer 52 may replace the function and role of the analysis server 56.

As described above, in a control system according to embodiments, an optical intensity of plasma reaction is classified into a soft arcing event and a hard arcing event according to its amplitude, and the number of occurrences of the soft arcing event during a given unit time is counted. If the number of occurrences of the soft arcing event during the given unit time is excessively greater than that during a previous unit time, it is predicted that the number of occurrences of the hard arcing event will increase during a next unit time.

As an increase in the number of the hard arcing events may cause plasma process fails, e.g., the plasma process may be used for an etching or deposition process in a chamber, the control system may output an interlock control signal when the increase in the number of occurrences of the hard arcing event is predicted. Therefore, input of wafers into the chamber may be stopped by the interlock control signal to allow cleaning of the chamber before resuming an etching or a deposition process of the wafers. Therefore, the method for controlling a plasma process of production equipment according to embodiments can effectively suppress plasma micro-arcing.

In contrast, since the arcing occurs due to the abnormality of plasma equipment or unpredictable reasons, arcing is merely controlled through follow-up in conventional methods. To date, there are few or no techniques for predicting arcing occurrences.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A method for predicting plasma micro-arcing, the method comprising:
obtaining a spectrum signal in a given plasma process;
classifying an optical intensity of the spectrum signal into a soft arcing event and a hard arcing event according to an amplitude of the optical intensity of the spectrum signal;
separately counting a number of occurrences of the soft arcing event in a given unit time;
comparing the number of occurrences of the soft arcing event during the given unit time with the number of occurrences of the soft arcing event during a previous unit time; and
determining that a number of occurrences of the hard arcing event will increase during a next unit time subsequent to the given unit time, when the number of occurrences of the soft arcing event during the given unit time increases in comparison with the number of occurrences of the soft arcing event during the previous unit time.

2. The method as claimed in claim 1, wherein the soft arcing event and the hard arcing event are calculated from a distribution function having a variable of a standard deviation and an optical intensity amplitude.

3. The method as claimed in claim 2, wherein the distribution function includes a normal distribution function.

4. The method as claimed in claim 3, wherein the number of occurrences of the soft arcing event is counted in a logarithmic scale distribution function which is transformed from the normal distribution function.

5. The method as claimed in claim 4, wherein the logarithmic scale distribution function has a normal section, a soft arcing section, and a hard arcing section.

6. The method as claimed in claim 5, wherein the soft arcing section includes a first soft arcing section of a first arcing events and a second soft arcing section of a second arcing events.

7. The method as claimed in claim 6, wherein the first soft arcing section ranges between 8×standard deviation and 11×standard deviation in the logarithmic scale function or the normal distribution function, and the second soft arcing section ranges between 11×standard deviation and 15×standard deviation in the logarithmic scale function or the normal distribution function.

8. The method as claimed in claim 7, wherein determining that the number of occurrences of the hard arcing event will increase during a next unit time includes determining that the number of the second soft arcing events in the second soft arcing section during the given unit time is greater than the number of the second soft arcing events during the previous unit time by a threshold value or more.

9. The method as claimed in claim 8, wherein each of the unit times ranges from about 36 minutes to about 60 minutes, and the threshold value of the number of occurrences of the second soft arcing event is about 300.

10. The method as claimed in claim 9, wherein each of the unit times includes a plurality of sub-unit times, and the number of occurrences of the second soft arcing event is cumulatively counted during the plurality of sub-unit times.

11. The method as claimed in claim 5, wherein the hard arcing section ranges between 15×standard deviation and 20×standard deviation in the logarithmic scale function or the normal distribution function.

12. The method as claimed in claim 1, further comprising removing a noise from the spectrum signal.

13. A method for controlling a plasma process of production equipment, the method comprising:
obtaining a spectrum signal from a plasma reaction in a chamber;
obtaining a high-frequency signal by removing a noise from the spectrum signal;
calculating at least one distribution function having a soft arcing section of a soft arcing event and a hard arcing section of a hard arcing event depending on an optical intensity of the high-frequency signal;
transforming the distribution function to a logarithmic scale function;
separately counting a number of occurrences of the soft arcing event in a given unit time during the soft arcing section in the logarithmic scale function;
comparing the number of occurrences of the soft arcing event during the given unit time with the number of occurrences of the soft arcing event during a previous unit time; and
determining that number of occurrences of the hard arcing event will increase during a next unit time subsequent to the given unit time, and outputting an interlock control signal to allow the plasma reaction not to be continuously performed during the next unit time, when the number of occurrences of the soft arcing event during the given unit time increases in comparison with that during the previous unit time.

14. The method as claimed in claim 13, further comprising cleaning the chamber after outputting the interlock control signal.

15. The method as claimed in claim 14, wherein the cleaning of the chamber includes in-situ dry cleaning.

16. A method for controlling a plasma process of production equipment, the method comprising:
obtaining a spectrum signal of a given plasma process in a chamber;
classifying an optical intensity of the spectrum signal into a soft arcing event and a hard arcing event according to an amplitude of the optical intensity of the spectrum signal;
separately counting a number of occurrences of the soft arcing event in a given unit time;
comparing the number of occurrences of the soft arcing event during the given unit time with the number of occurrences of the soft arcing event during a previous unit time; and
outputting an interlock control signal to discontinue the plasma process in the chamber, when the number of occurrences of the soft arcing event during the given unit time increases in comparison with the number of occurrences of the soft arcing event during the previous unit time.

17. The method as claimed in claim 16, wherein counting the number of occurrences of the soft arcing event in the given unit time includes counting the number of occurrences of the soft arcing event during an entire process stage of a predetermined number of objects in the chamber.

18. The method as claimed in claim 17, wherein outputting the interlock signal occurs before inputting new objects into the chamber for the process stage.

19. The method as claimed in claim 17, wherein the previous unit of time is a predetermined reference value.

20. The method as claimed in claim 17, wherein the previous unit of time is measured during an entire process stage of a predetermined number of previous objects in the chamber.
